(19) United States
(12) Patent Application Publication
(10) Pub. No.: US 2023/0261633 A1
(43) Pub. Date: Aug. 17, 2023

(54) LAYERED TEMPERATURE-COMPENSATED SURFACE ACOUSTIC WAVE RESONATOR AND PACKAGING METHOD

(71) Applicant: Spreadtrum Communications (Shanghai) Co., Ltd., Shanghai (CN)

(72) Inventor: Jing CHEN, Shanghai (CN)

(73) Assignee: Spreadtrum Communications (Shanghai) Co., Ltd., Shanghai (CN)

(21) Appl. No.: 18/137,749

(22) Filed: Apr. 21, 2023

Related U.S. Application Data
(63) Continuation of application No. PCT/CN2021/125505, filed on Oct. 22, 2021.

(30) Foreign Application Priority Data
Oct. 22, 2020 (CN) 2020111409031

(51) Int. Cl. H03H 9/02; H03H 9/145; H03H 3/08

(52) U.S. Cl. CPC H03H 9/02834; H03H 9/145; H03H 9/02559; H03H 3/08

(57) ABSTRACT

A layered temperature-compensated surface acoustic wave resonator. The layered temperature-compensated surface acoustic wave resonator includes a substrate layer, a temperature compensation layer, a piezoelectric film layer and an electrode layer. The temperature compensation layer is located between the substrate layer and the piezoelectric film layer; the substrate layer and the temperature compensation layer are integrated by wafer bonding, and the temperature compensation layer and the piezoelectric film layer are integrated by wafer bonding. The electrode layer is arranged on a surface of the piezoelectric film layer. The temperature compensation layer is made of a positive temperature coefficient material.

### CROSS-REFERENCE TO RELATED APPLICATIONS

This application is a continuation application of International Application No. PCT/CN2021/125505, filed on Oct. 22, 2021, which claims priority to Chinese Patent Application No. 202011140903.1, entitled “LAYERED TEMPERATURE-COMPENSATED SURFACE ACOUSTIC WAVE RESONATOR AND PACKAGING METHOD” and filed with the China National Intellectual Property Administration on Oct. 22, 2020. Both of the above applications are hereby incorporated by reference in their entireties.

### TECHNICAL FIELD

The present disclosure relates to the field of semiconductor technologies and, in particular, to a layered temperature-compensated surface acoustic wave resonator and a packaging method.

### BACKGROUND

Surface acoustic wave (abbreviated as SAW) filters have become indispensable key components in radio frequency (abbreviated as RF) front-end applications due to their small size, good performance, and low cost etc.

At present, with the application of 5G core technologies such as carrier aggregation (abbreviated as CA), massive antenna technology (Massive MIMO) and high-order quadrature amplitude modulation (abbreviated as QAM), the number of RF front-end components is largely increasing. In this case, more and more stringent technical requirements are put forward for the performance of a filter element. For example, a SAW resonator, which is a core unit constituting the filter element, is required to be of better temperature stability.

### SUMMARY

Embodiments of the present disclosure provide a layered temperature-compensated surface acoustic wave resonator and a packaging method

In a first aspect, the present disclosure provides a layered temperature-compensated surface acoustic wave resonator, including a substrate layer, a temperature compensation layer, a piezoelectric film layer and an electrode layer;

the temperature compensation layer is located between the substrate layer and the piezoelectric film layer; the substrate layer and the temperature compensation layer are integrated by wafer bonding, and the temperature compensation layer and the piezoelectric film layer are integrated by wafer bonding; the temperature compensation layer is made of a positive temperature coefficient material; and

the electrode layer is arranged on a surface of the piezoelectric film layer.

In a second aspect, the present disclosure provides a packaging method for a layered temperature-compensated surface acoustic wave resonator, including:

obtaining a substrate layer;

preparing a temperature compensation layer on the substrate layer, where the substrate layer and the temperature compensation layer are integrated by wafer bonding, and a positive temperature coefficient material is adopted for the temperature compensation layer;

preparing a piezoelectric film layer on the temperature compensation layer, where the temperature compensation layer and the piezoelectric film layer are integrated by wafer bonding; and

preparing an electrode layer on the piezoelectric film layer.

### BRIEF DESCRIPTION OF DRAWINGS

To illustrate the technical solutions in embodiments of the present disclosure or in the related art more clearly, the drawings required for describing the embodiments of the present disclosure or the related art will be briefly introduced below. Obviously, the accompanying drawings described below show some embodiments of the present disclosure, and persons of ordinary skill in the art may still derive other drawings from these accompanying drawings without creative efforts.

FIG. 1 is a schematic cross-sectional structural diagram of a layered temperature-compensated surface acoustic wave resonator in an embodiment of the present disclosure.

FIG. 2 is a schematic structural diagram of an electrode layer within a layered temperature-compensated surface acoustic wave resonator provided in an embodiment of the present disclosure.

FIG. 3 is schematic diagram I of parameter simulation of a layered temperature-compensated surface acoustic wave resonator provided in an embodiment of the present disclosure.

FIG. 4 is schematic diagram II of parameter simulation of a layered temperature-compensated surface acoustic wave resonator provided in an embodiment of the present disclosure.

FIG. 5 is schematic diagram III of parameter simulation of a layered temperature-compensated surface acoustic wave resonator provided in an embodiment of the present disclosure.

FIG. 6 is schematic diagram IV of parameter simulation of a layered temperature-compensated surface acoustic wave resonator provided in an embodiment of the present disclosure.

FIG. 7 is schematic diagram V of parameter simulation of a layered temperature-compensated surface acoustic wave resonator provided in an embodiment of the present disclosure.

FIG. 8 is schematic diagram VI of parameter simulation of a layered temperature-compensated surface acoustic wave resonator provided in an embodiment of the present disclosure.

FIG. 9 is a schematic flowchart of a packaging method for a layered temperature-compensated surface acoustic wave resonator provided in an embodiment of the present disclosure.

### DESCRIPTION OF EMBODIMENTS

To make the objectives, technical solutions and advantages of embodiments of the present disclosure clearer, the following clearly and comprehensively describes the technical solutions in the embodiments of the present disclosure with reference to the accompanying drawings in the embodiments of the present disclosure. Apparently, the described embodiments are some but not all of the embodiments of the present disclosure. All other embodiments obtained by persons of ordinary skill in the art based on the embodiments in the present disclosure without creative efforts shall fall within the protection scope of the present disclosure.

Related surface acoustic wave resonators are usually formed by sequentially stacking a substrate, a piezoelectric film and an electrode layer. However, this structure is easily affected by ambient temperature, and the temperature stability thereof is poor. It is difficult for this structure to meet high performance requirements for current filters.

Therefore, how to improve the temperature stability of a surface acoustic wave resonator is an urgent problem to be solved.

In order to solve the above technical problems, an embodiment of the present disclosure provides a layered temperature-compensated surface acoustic wave resonator, including a substrate layer, a temperature compensation layer, a piezoelectric film layer and an electrode layer, where the temperature compensation layer is located between the substrate layer and the piezoelectric film layer; the substrate layer and the temperature compensation layer are integrated by wafer bonding, and the temperature compensation layer and the piezoelectric film layer are integrated by wafer bonding; and the temperature compensation layer is made of a positive temperature coefficient material, thereby effectively eliminating an influence of temperature on the surface acoustic wave resonator and enhancing the temperature stability of the surface acoustic wave resonator. Reference for details may be made to descriptions in the following embodiments.

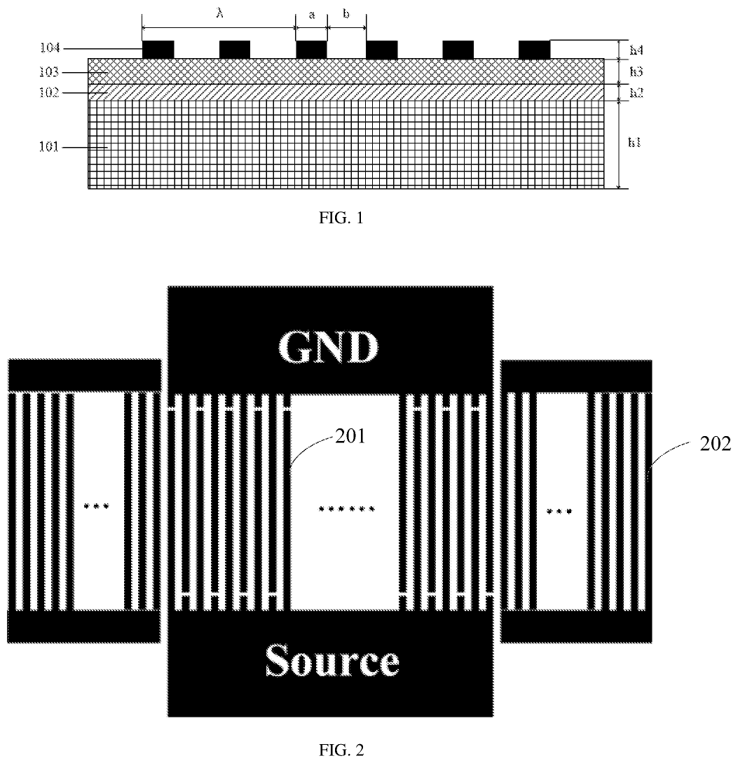

Please refer to FIG. 1. FIG. 1 is a schematic cross-sectional structural diagram of a layered temperature-compensated surface acoustic wave resonator in an embodiment of the present disclosure. In FIG. 1, the layered temperature-compensated surface acoustic wave resonator includes a substrate layer 101, a temperature compensation layer 102, a piezoelectric film layer 103 and an electrode layer 104.

The temperature compensation layer 102 is located between the substrate layer 101 and the piezoelectric film layer 103. The substrate layer 101 and the temperature compensation layer 102 are integrated by wafer bonding, and the temperature compensation layer 102 and the piezoelectric film layer 103 are also integrated by wafer bonding. The electrode layer 104 is arranged on a surface of the piezoelectric film layer 103.

Wafer bonding refers to close combination of two mirror-polished homogeneous or heterogeneous wafers through chemical and physical action. After the wafers are bonded, atoms at an interface are reacted under external forces to form covalent bonds, and are thus integrated, allowing a specific bonding strength at the joint interface. In this embodiment, utilization of wafer bonding is beneficial to realization of the low-temperature drift and the power tolerance performance of the resonator.

It should be noted that thicknesses of respective material layers of the layered temperature-compensated surface acoustic wave resonator shown in FIG. 1 are only for illustration and do not represent actual thicknesses.

In an embodiment, the temperature compensation layer 102 is made of a positive temperature coefficient material.

Illustratively, the temperature compensation layer 102 may be made of SiO₂.

In a feasible implementation, the electrode layer 104 is an interdigital electrode layer, and the interdigital electrode layer may be made of at least one of the following materials: aluminum, copper, gold and an aluminum-copper alloy.

In a feasible implementation, the piezoelectric film layer 103 may be made of at least one of the following materials: lithium tantalate LiTaO₃, lithium niobate LiNbO₃.

In a feasible implementation, the substrate layer 101 may be made of at least one of the following materials: silicon Si, silicon carbide SiC and sapphire.

As shown in FIG. 1, an interdigital electrode (Interdigital Transducer, IDT) may be adopted for the electrode layer 104. Assuming that a width of the interdigital electrode is a and that a gap between adjacent interdigital electrodes is b, then a half period of the interdigital electrode is p, where p=a+b, and a wavelength corresponding to the interdigital electrode is λ, where λ=2p.

In a feasible implementation, a value of thickness h1 of the substrate layer 101 may range from 30λ to 150λ; a value of thickness h2 of the temperature compensation layer 102 may range from 0.05λ to 2.0λ; a value of thickness h3 of the piezoelectric film layer 103 may range from 0.05λ to 10λ; and a value of thickness h4 of the electrode layer 104 may range from 0.06λ to 0.15λ.

In the embodiment of the present disclosure, by optimizing parameters of materials of respective layers in the above surface acoustic wave resonator, it can also be ensured that the surface acoustic wave resonator has a higher electromechanical coupling coefficient, thus facilitating the implementation of a filter with low-temperature drift, high frequency and large bandwidth.

Based on the description in the above embodiment, please refer to FIG. 2. FIG. 2 is a schematic structural diagram of an electrode layer within a layered temperature-compensated surface acoustic wave resonator provided in an embodiment of the present disclosure.

In FIG. 2, the electrode layer 104 includes an interdigital electrode 201. Both sides of the interdigital electrode 201 include a reflection grating 202, and ground GND and excitation Source are interchangeable. In addition, parameters such as the number of pairs or fingers of the interdigital electrode 201 and the reflection grating 202 can be determined according to a specific design, and are not limited in this embodiment.

Based on the description in the above-mentioned embodiments, a temperature-compensated surface acoustic wave resonator with high sound velocity and high electromechanical coupling coefficient can be obtained by optimizing parameters of materials of respective layers in the above surface acoustic wave resonator. These performance improvements much facilitate the implementation of a filter with low-temperature drift, high frequency and large bandwidth, and can alleviate the difficulty of process processing to a certain extent and improve the performance such as device yield and power tolerance.

Specifically, in a feasible implementation of the present disclosure, the substrate layer is made of SiC, the temperature compensation layer is made of SiO₂, the piezoelectric film layer is made of LiTaO₃, and the electrode layer is made of gold.

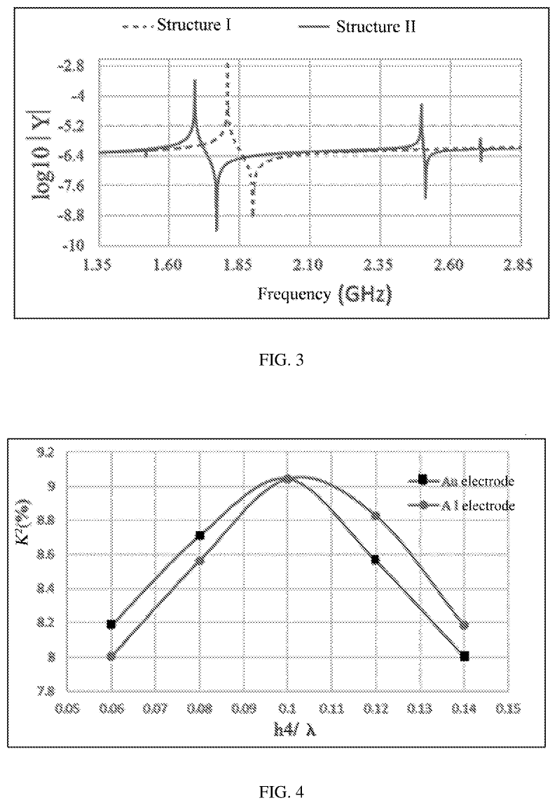

Please refer to FIG. 3. FIG. 3 is schematic diagram I of parameter simulation of a layered temperature-compensated surface acoustic wave resonator provided in an embodiment of the present disclosure. Admittance performance of structures of two types of layered temperature-compensated surface acoustic wave resonators is compared in FIG. 3.

It is assumed that λ=1.7 μm, a metallization ratio is defined as R=a/p, R=0.5, and in response curves of the resonators, logarithmic values are taken for all the admittance: log 10|Y|. A formula for calculating an electromechanical coupling coefficient K² is: K²=π×fᵣ/(2fₐ×tan(πfᵣ/2fₐ)), where fₐ is a resonant frequency of a resonator and fₐ is an anti-resonant frequency.

When “Structure I” is adopted for the above-mentioned layered temperature-compensated surface acoustic wave resonator, the substrate layer is made of SiC, the temperature compensation layer is made of SiO₂, the piezoelectric film layer is made of LiTaO₃, and an interdigital electrode is adopted for the electrode layer. As shown in FIG. 3, the resonant frequency fᵣ and the anti-resonant frequency fₐ of the above-mentioned layered temperature-compensated surface acoustic wave resonator are fᵣ≅1.81 GHz and fₐ≅1.9 GHz, respectively.

When “Structure II” is adopted for the above-mentioned layered temperature-compensated surface acoustic wave resonator, the substrate layer is made of Si, the temperature compensation layer is made of SiO₂, the piezoelectric film layer is made of LiTaO₃, and an interdigital electrode is adopted for the electrode layer. As shown in FIG. 3, the resonant frequency fᵣ and the anti-resonant frequency fₐ of the above-mentioned layered temperature-compensated surface acoustic wave resonator are fᵣ≅1.69 GHz and fₐ≅1.77 GHz, respectively.

In the above-mentioned “Structure I” and “Structure II”, the thickness h1 of the substrate layer is h1=110λ, the thickness h2 of the temperature compensation layer is h2=0.25λ, the thickness h3 of the piezoelectric film layer is h3=0.1, and the thickness h4 of the electrode layer is h4=0.1λ.

Since SiC is harder than Si, a speed of sound propagation in SiC is correspondingly higher than a speed of sound propagation in the Si substrate. It can be clearly seen that an operating frequency of the substrate made of SiC is higher than that of the substrate made of Si under the condition of using the same temperature compensation layer, the same piezoelectric film layer and the same electrode layer. Therefore, for devices that require high frequency, materials with high hardness such as SiC can be selected as the substrate. Implementation of resonators with the same operating frequency by such materials can alleviate the difficulty of process processing to a certain extent, and improve the performance such as device yield and power tolerance.

Please refer to FIG. 4. FIG. 4 is schematic diagram II of parameter simulation of a layered temperature-compensated surface acoustic wave resonator provided in an embodiment of the present disclosure. Electromechanical coupling coefficients of structures of two types of layered temperature-compensated surface acoustic wave resonators are compared in FIG. 4.

In this embodiment, the thickness h1 of the substrate layer is set as h1=110λ, the thickness h2 of the temperature compensation layer is set as h2=0.25λ, and the thickness h3 of the piezoelectric film layer is set as h3=0.1λ.

It can be seen from FIG. 4 that when an Au (gold) electrode or an Al (aluminum) electrode is adopted for the electrode layer, the thickness of the electrode layer is different, and the electromechanical coupling coefficient K² of the above-mentioned layered temperature-compensated surface acoustic wave resonator is also different. Each peak value corresponding to the electromechanical coupling coefficient K² appears as the thickness of the electrode layer is about 0.1λ.

When the same electromechanical coupling coefficient is reached, the Al electrode is generally thicker than the Au electrode.

Based on the above analysis, it can be seen that in the embodiment of the present disclosure, when the substrate layer, the temperature compensation layer, the piezoelectric film layer and the electrode layer mentioned above are made of SiC, SiO₂, LiTaO₃ and Au, respectively, the resonator can have smaller size and better performance such as better power tolerance.

In another feasible implementation of the present disclosure, the substrate layer is made of SiC, the temperature compensation layer is made of SiO₂, and the piezoelectric film layer is made of LiTaO₃.

The thickness h1 of the substrate layer is 110, the thickness h2 of the temperature compensation layer is 0.25λ, the thickness h3 of the piezoelectric film layer is 0.1λ, and the thickness h4 of the electrode layer is 0.1λ.

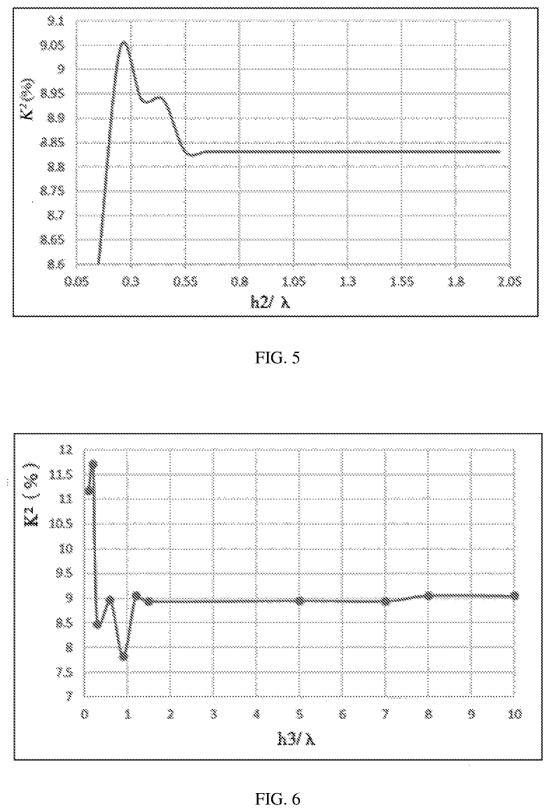

Please refer to FIG. 5. FIG. 5 is schematic diagram III of parameter simulation of a layered temperature-compensated surface acoustic wave resonator provided in an embodiment of the present disclosure.

It can be seen from FIG. 5 that when the thickness h2 of the temperature compensation layer is about 0.25λ, the electromechanical coupling coefficient K² of the layered temperature-compensated surface acoustic wave resonator reaches a peak value and K² 9.05%. When h2 is about 0.55λ to 2.05λ and above, the electromechanical coupling coefficient K² of the layered temperature-compensated surface acoustic wave resonator is relatively stable and K²=8.83%.

Please refer to FIG. 6. FIG. 6 is schematic diagram IV of parameter simulation of a layered temperature-compensated surface acoustic wave resonator provided in an embodiment of the present disclosure.

It can be seen from FIG. 6 that when the thickness h3 of the piezoelectric film layer is about 0.1λ, the electromechanical coupling coefficient K² of the layered temperature-compensated surface acoustic wave resonator reaches a peak value and K²=11.75%. When the thickness h3 of the piezoelectric film layer is about 1.2λ to 10λ and above, the electromechanical coupling coefficient K² of the layered temperature-compensated surface acoustic wave resonator is relatively stable and K²=9%.

Based on the above analysis, it can be seen that in the embodiment of the present disclosure, when the substrate layer, the temperature compensation layer and the piezoelectric film layer mentioned above are made of SiC, SiO₂ and LiTaO₃, respectively, and when the thickness h1 of the substrate layer is 110, the thickness h2 of the temperature compensation layer is 0.25λ, the thickness h3 of the piezoelectric film layer is 0.1λ, and the thickness h4 of the electrode layer is 0.1λ, the temperature-compensated surface acoustic wave resonator can have a higher electromechanical coupling coefficient.

In yet another feasible implementation of the present disclosure, the substrate layer is made of SiC, the temperature compensation layer is made of SiO₂, and the piezoelectric film layer is made of LiTaO₃.

The thickness h1 of the substrate layer is 110, the thickness h2 of the temperature compensation layer is 0.25λ, the thickness h3 of the piezoelectric film layer is 0.25λ, and the thickness h4 of the electrode layer is 0.1λ.

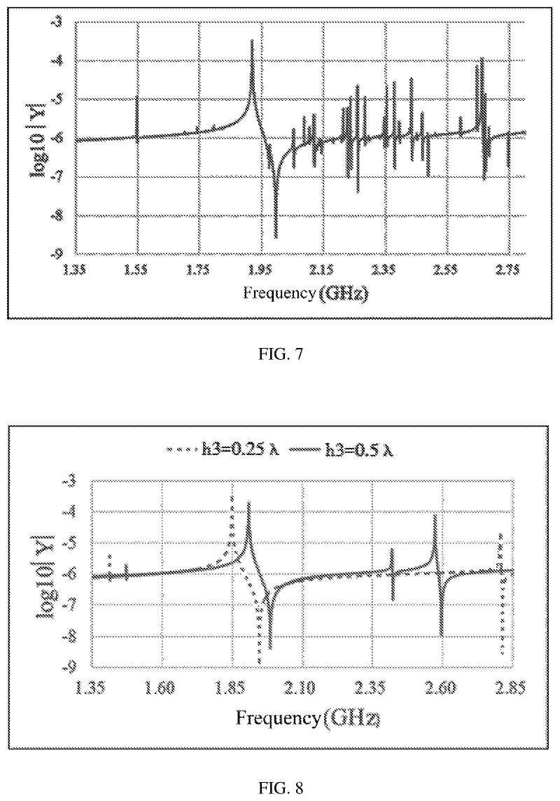

Please refer to FIG. 7. FIG. 7 is schematic diagram V of parameter simulation of a layered temperature-compensated surface acoustic wave resonator provided in an embodiment of the present disclosure.

In FIG. 7, the thickness h1 of the substrate layer is set as h1=110λ, the thickness h2 of the temperature compensation layer is set as h2=0.25λ, the thickness h3 of the piezoelectric film layer is set as h3=8λ, and the thickness h4 of the electrode layer is set as h4=0.1λ.

It can be seen from FIG. 7 that when the thickness h3 of the piezoelectric film layer is 8λ, clutters appear at dominant mode frequencies of 1.9 GHz to 2.05 GHz and at high and low dominant mode frequencies, especially at high frequencies. These clutters may degrade the passband and out-of-band performance of the filter, and thus need to be suppressed as much as possible.

Please refer to FIG. 8. FIG. 8 is schematic diagram VI of parameter simulation of a layered temperature-compensated surface acoustic wave resonator provided in an embodiment of the present disclosure.

In FIG. 8, the thickness h1 of the substrate layer set as h1=110λ, the thickness h2 of the temperature compensation layer is set as h2=0.25λ, and the thickness h4 of the electrode layer is set as h4=0.1λ.

It can be seen from FIG. 8 that when the thickness h3 of the piezoelectric film layer is 0.25λ, clutters can be better suppressed than the case when h3 is 0.5λ.

For example, when the thickness h3 of the piezoelectric film layer is 0.25λ, clutters at high frequencies (2.4 GHz to 2.6 GHz) can be suppressed relatively well, and only one clutter appears at a higher frequency (2.8 GHz).

Based on the above analysis, it can be seen that in the embodiment of the present disclosure, when the substrate layer, the temperature compensation layer and the piezoelectric film layer mentioned above are made of SiC, SiO₂, and LiTaO₃, respectively, and when the thickness h1 of the substrate layer is 110λ, the thickness h2 of the temperature compensation layer is 0.25λ, the thickness h3 of the piezoelectric film layer is 0.25λ, and the thickness h4 of the electrode layer is 0.1λ, the above-mentioned temperature-compensated surface acoustic wave resonator can effectively suppress clutters at high frequencies.

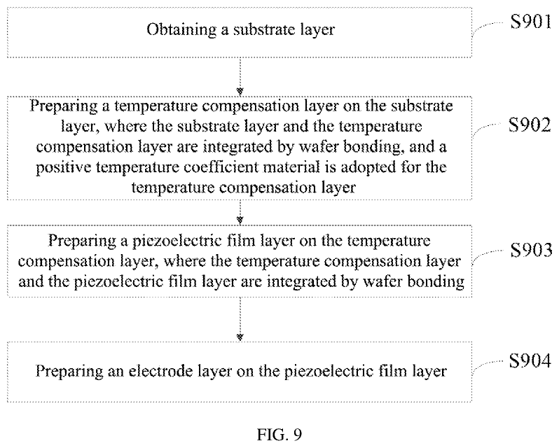

Further, based on the descriptions in the above embodiments, an embodiment of the present disclosure further provides a packaging method for a layered temperature-compensated surface acoustic wave resonator. Please refer to FIG. 9. FIG. 9 is a schematic flowchart of a packaging method for a layered temperature-compensated surface acoustic wave resonator provided in an embodiment of the present disclosure. In the embodiment of the present disclosure, the above packaging method includes:

S901: obtaining a substrate layer;

S902: preparing a temperature compensation layer on the substrate layer, where the substrate layer and the temperature compensation layer are integrated by wafer bonding, and a positive temperature coefficient material is adopted for the temperature compensation layer;

S903: preparing a piezoelectric film layer on the temperature compensation layer, where the temperature compensation layer and the piezoelectric film layer are integrated by wafer bonding; and

S904: preparing an electrode layer on the piezoelectric film layer.

In a feasible implementation, the temperature compensation layer is made of SiO₂.

In a feasible implementation, the electrode layer is an interdigital electrode layer, and the interdigital electrode layer is made of at least one of the following materials: aluminum, copper, gold and an aluminum-copper alloy.

In a feasible implementation, the piezoelectric film layer is made of at least one of the following materials: LiTaO₃, LiNbO₃.

In a feasible implementation, the substrate layer is made of at least one of the following materials: Si and SiC.

In a feasible implementation, a thickness of the electrode layer ranges from 0.06λ to 0.15λ, a thickness of the piezoelectric film layer ranges 0.05λ to 10λ, a thickness of the temperature compensation layer ranges from 0.05λ to 2.0λ, and a thickness of the substrate layer ranges from 30λ to 150λ, where λ is a wavelength corresponding to the electrode layer.

In a feasible implementation, the substrate layer is made of SiC, the temperature compensation layer is made of SiO₂, the piezoelectric film layer is made of LiTaO₃, and the electrode layer is made of gold.

In a feasible implementation, the substrate layer is made of SiC, the temperature compensation layer is made of SiO₂, and the piezoelectric film layer is made of LiTaO₃; and the thickness of the temperature compensation layer is 0.25λ, the thickness of the piezoelectric film layer is 0.1λ, the thickness of the electrode layer is 0.1λ, and the thickness of the substrate layer is 110λ.

In a feasible implementation, the substrate layer is made of SiC, the temperature compensation layer is made of SiO₂, and the piezoelectric film layer is made of LiTaO₃; and the thickness of the temperature compensation layer is 0.25λ, the thickness of the piezoelectric film layer is 0.25λ, the thickness of the electrode layer is 0.1λ, and the thickness of the substrate layer is 110λ.

In the packaging method for the layered temperature-compensated surface acoustic wave resonator provided in the embodiments of the present disclosure, the temperature compensation layer is further prepared between the substrate layer and the piezoelectric film layer of the surface acoustic wave resonator, and the temperature compensation layer is made of the positive temperature coefficient material, thus effectively enhancing temperature stability of the surface acoustic wave resonator. In addition, by optimizing parameters of materials of respective layers in the surface acoustic wave resonator, it can also be ensured that the surface acoustic wave resonator has a higher electromechanical coupling coefficient, thus facilitating the implementation of a filter with low-temperature drift, high frequency and large bandwidth.

Finally, it should be noted that the above embodiments are merely used for illustrating the technical solutions of the present disclosure, rather than limiting them. Although the present disclosure has been described in detail with reference to the foregoing embodiments, those skilled in the art should understand that they may still modify the technical solutions described in the foregoing embodiments, or make equivalent substitutions for some or all of the technical features therein. These modifications or substitutions do not make the essence of the corresponding technical solutions deviate from the scope of the technical solutions of various embodiments of the present disclosure.

Embodiments of the present disclosure provide a layered temperature-compensated surface acoustic wave resonator and a packaging method, which can effectively improve the temperature stability of the surface acoustic wave resonator.

In a first aspect, the present disclosure provides a layered temperature-compensated surface acoustic wave resonator, including a substrate layer, a temperature compensation layer, a piezoelectric film layer and an electrode layer;

the temperature compensation layer is located between the substrate layer and the piezoelectric film layer; the substrate layer and the temperature compensation layer are integrated by wafer bonding, and the temperature compensation layer and the piezoelectric film layer are integrated by wafer bonding; the temperature compensation layer is made of a positive temperature coefficient material; and

the electrode layer is arranged on a surface of the piezoelectric film layer.

In a feasible implementation, the temperature compensation layer is made of SiO₂.

In a feasible implementation, the electrode layer is an interdigital electrode layer, and the interdigital electrode layer is made of at least one of the following materials: aluminum, copper, gold and an aluminum-copper alloy.

In a feasible implementation, the piezoelectric film layer is made of at least one of the following materials: lithium tantalate LiTaO₃, lithium niobate LiNbO₃.

In a feasible implementation, the substrate layer is made of at least one of the following materials: silicon Si, silicon carbide SiC, sapphire.

In a feasible implementation, a thickness of the electrode layer ranges from 0.06λ to 0.15λ, a thickness of the piezoelectric film layer ranges from 0.05λ to 10λ, a thickness of the temperature compensation layer ranges from 0.05λ to 2.0λ, and a thickness of the substrate layer ranges from 30λ to 150λ, where λ is a wavelength corresponding to the electrode layer.

In a feasible implementation, the substrate layer is made of SiC, the temperature compensation layer is made of SiO₂, the piezoelectric film layer is made of LiTaO₃, and the electrode layer is made of gold.

In a feasible implementation, the substrate layer is made of SiC, the temperature compensation layer is made of SiO₂, and the piezoelectric film layer is made of LiTaO₃; and the thickness of the temperature compensation layer is 0.25λ, the thickness of the piezoelectric film layer is 0.1λ, the thickness of the electrode layer is 0.1λ, and the thickness of the substrate layer is 110λ.

In a feasible implementation, the substrate layer is made of SiC, the temperature compensation layer is made of SiO₂, and the piezoelectric film layer is made of LiTaO₃; and the thickness of the temperature compensation layer is 0.25λ, the thickness of the piezoelectric film layer is 0.25λ, the thickness of the electrode layer is 0.1λ, and the thickness of the substrate layer is 110λ.

In a second aspect, the present disclosure provides a packaging method for a layered temperature-compensated surface acoustic wave resonator, including:

obtaining a substrate layer;

preparing a temperature compensation layer on the substrate layer, where the substrate layer and the temperature compensation layer are integrated by wafer bonding, and a positive temperature coefficient material is adopted for the temperature compensation layer;

preparing a piezoelectric film layer on the temperature compensation layer, where the temperature compensation layer and the piezoelectric film layer are integrated by wafer bonding; and

preparing an electrode layer on the piezoelectric film layer.

In the layered temperature-compensated surface acoustic wave resonator and the packaging method provided by the embodiments of the present disclosure, the layered temperature-compensated surface acoustic wave resonator includes the substrate layer, the temperature compensation layer, the piezoelectric film layer and the electrode layer. The temperature compensation layer is located between the substrate layer and the piezoelectric film layer; the substrate layer and the temperature compensation layer are integrated by wafer bonding, and the temperature compensation layer and the piezoelectric film layer are integrated by wafer bonding. The electrode layer is arranged on the surface of the piezoelectric film layer. The temperature compensation layer is made of the positive temperature coefficient material, thereby effectively enhancing the temperature stability of the surface acoustic wave resonator. By optimizing parameters of materials of respective layers in the above surface acoustic wave resonator, it can also be ensured that the surface acoustic wave resonator has a higher electromechanical coupling coefficient, thus facilitating the implementation of a filter with low-temperature drift, high frequency and large bandwidth.

What is claimed is:

1. A layered temperature-compensated surface acoustic wave resonator, comprising a substrate layer, a temperature compensation layer, a piezoelectric film layer and an electrode layer;
wherein the temperature compensation layer is located between the substrate layer and the piezoelectric film layer; the substrate layer and the temperature compensation layer are integrated by wafer bonding, and the temperature compensation layer and the piezoelectric film layer are integrated by wafer bonding; the temperature compensation layer is made of a positive temperature coefficient material; and
the electrode layer is arranged on a surface of the piezoelectric film layer.

2. The layered temperature-compensated surface acoustic wave resonator according to claim 1, wherein the temperature compensation layer is made of silicon dioxide SiO₂.

3. The layered temperature-compensated surface acoustic wave resonator according to claim 1, wherein the electrode layer is an interdigital electrode layer, and the interdigital electrode layer is made of at least one of the following materials: aluminum, copper, gold and an aluminum-copper alloy.

4. The layered temperature-compensated surface acoustic wave resonator according to claim 1, wherein the piezoelectric film layer is made of at least one of the following materials: lithium tantalate LiTaO₃, lithium niobate LiNbO₃.

5. The layered temperature-compensated surface acoustic wave resonator according to claim 1, wherein the substrate layer is made of at least one of the following materials: silicon Si, silicon carbide SiC and sapphire.

6. The layered temperature-compensated surface acoustic wave resonator according to claim 1, wherein a thickness of the substrate layer ranges from 30λ to 150λ, a thickness of the temperature compensation layer ranges from 0.05λ to 2.0λ, a thickness of the piezoelectric film layer ranges from 0.05λ to 10λ, and a thickness of the electrode layer ranges from 0.06λ to 0.15λ, wherein λ is a wavelength corresponding to the electrode layer.

7. The layered temperature-compensated surface acoustic wave resonator according to claim 2, wherein a thickness of the substrate layer ranges from 30λ to 150λ, a thickness of the temperature compensation layer ranges from 0.05λ to 2.0λ, a thickness of the piezoelectric film layer ranges from 0.05λ to 10λ, and a thickness of the electrode layer ranges from 0.06λ to 0.15λ, wherein λ is a wavelength corresponding to the electrode layer.

8. The layered temperature-compensated surface acoustic wave resonator according to claim 3, wherein a thickness of the substrate layer ranges from 30λ to 150λ, a thickness of the temperature compensation layer ranges from 0.05λ to 2.0λ, a thickness of the piezoelectric film layer ranges from 0.05λ to 10λ, and a thickness of the electrode layer ranges from 0.06λ to 0.15λ, wherein λ is a wavelength corresponding to the electrode layer.

9. The layered temperature-compensated surface acoustic wave resonator according to claim 4, wherein a thickness of the substrate layer ranges from 30λ to 150λ, a thickness of the temperature compensation layer ranges from 0.05λ to 2.0λ, a thickness of the piezoelectric film layer ranges from 0.05λ to 10λ, and a thickness of the electrode layer ranges from 0.06λ to 0.15λ, wherein λ is a wavelength corresponding to the electrode layer.

10. The layered temperature-compensated surface acoustic wave resonator according to claim 5, wherein a thickness of the substrate layer ranges from 30λ to 150λ, a thickness of the temperature compensation layer ranges from 0.05λ to 2.0λ, a thickness of the piezoelectric film layer ranges from 0.05λ to 10λ, and a thickness of the electrode layer ranges from 0.06λ to 0.15λ, wherein λ is a wavelength corresponding to the electrode layer.

11. The layered temperature-compensated surface acoustic wave resonator according to claim 6, wherein the substrate layer is made of SiC, the temperature compensation layer is made of SiO₂, the piezoelectric film layer is made of LiTaO₃, and the electrode layer is made of gold.

12. The layered temperature-compensated surface acoustic wave resonator according to claim 6, wherein the substrate layer is made of SiC, the temperature compensation layer is made of SiO₂, and the piezoelectric film layer is made of LiTaO₃; and
the thickness of the substrate layer is 110λ, the thickness of the temperature compensation layer is 0.25λ, the thickness of the piezoelectric film layer is 0.1λ, and the thickness of the electrode layer is 0.1λ.

13. The layered temperature-compensated surface acoustic wave resonator according to claim 6, wherein the substrate layer is made of SiC, the temperature compensation layer is made of SiO₂, and the piezoelectric film layer is made of LiTaO₃; and
the thickness of the substrate layer is 110λ, the thickness of the temperature compensation layer is 0.25λ, the thickness of the piezoelectric film layer is 0.25λ, and the thickness of the electrode layer is 0.1λ.

14. A packaging method for a layered temperature-compensated surface acoustic wave resonator, comprising:
obtaining a substrate layer;
preparing a temperature compensation layer on the substrate layer, wherein the substrate layer and the temperature compensation layer are integrated by wafer bonding, and a positive temperature coefficient material is adopted for the temperature compensation layer;
preparing a piezoelectric film layer on the temperature compensation layer, wherein the temperature compensation layer and the piezoelectric film layer are integrated by wafer bonding; and
preparing an electrode layer on the piezoelectric film layer.
